(19) United States
(12) Patent Application Publication
(10) Pub. No.: US 2021/0212238 A1
(43) Pub. Date: Jul. 8, 2021

(54) SERVER HEAT DISSIPATION STRUCTURE

(71) Applicants: INVENTEC (PUDONG) TECHNOLOGY CORPORATION, Shanghai City (CN); INVENTEC CORPORATION, Taipei City (TW)

(72) Inventors: Guang-Zhao TIAN, Shanghai City (CN); Wei WANG, Shanghai City (CN)

(73) Assignees: INVENTEC (PUDONG) TECHNOLOGY CORPORATION, Shanghai City (CN); INVENTEC CORPORATION, Taipei City (TW)

(21) Appl. No.: 16/796,752

(22) Filed: Feb. 20, 2020

(30) Foreign Application Priority Data
Jan. 3, 2020 (CN) 202010006234.2

(51) Int. Cl. H05K 7/20

(52) U.S. Cl. CPC H05K 7/20172; H05K 7/20727; H05K 7/20245; H05K 7/20672; H05K 7/208; H05K 7/2029

(57) ABSTRACT

A server heat dissipation structure, configured to dissipate the heat of a host casing of a dense type server. The server heat dissipation structure includes a thermosiphon heat sink and a fan assembly. The thermosiphon heat sink includes a heat absorbing end and a heat dissipation end that are connected via a connection tube. The fan assembly is disposed on a side of the heat dissipation end so as to help the heat dissipation of the heat dissipation end.

### CROSS-REFERENCE TO RELATED APPLICATIONS

This non-provisional application claims priority under 35 U.S.C. § 119(a) on Patent Application No(s). 202010006234.2 filed in China, on Jan. 3, 2020, the entire contents of which are hereby incorporated by reference.

### BACKGROUND OF THE INVENTION

### Technical Field of the Invention

The invention relates to computer technology field, more particularly to a server heat dissipation structure.

### Description of the Related Art

In the internet era, the exchange of electronic information is highly depending on servers, and the active response is the key to reflect the quality of user experience. As news often report, a large number of visitors in a very short period of time may cause platforms or applications (APP) to break down. And this is the important effect that the servers exert in the electronic information era.

Since the importance of servers, how to build up a server platform and how to ensure the high efficient operation of the server are also important. According to the daily experiences of using a typical computer, the computer generates a more significant amount of heat during operation. The personal computer usually contains one processor, but the servers mostly have multiple processors operating at the same time, no less than 2 and may up to ten-something, thus, the heat dissipation of the server is very critical.

The typical heat dissipation for servers uses air-cooling system cooperated with air conditioning unit. This solution may be workable in winter or cold areas but may become a tough problem in summer or in hot areas. Some countries employ oil cooling, this solution can reduce the noise and temperature but is costly and has a high risk coefficient, being unsuitable for wide application.

Liquid-cooling solution is a preferable option for the heat dissipation of server. Since the great success of the liquid-cooling in the common computers, the liquid-cooling system should be suitable for being applied to the servers. The massively produced water blocks cooperated with one-piece of tubing and radiator can effectively reduce the temperature, and the cost would be more controllable. Therefore, the liquid-cooling is suitable for enterprise servers.

In the current market, the liquid-cooling heat dissipation devices for servers are often limited by the room for accommodating it. Also, the other factors, such as the volume of the liquid-cooling heat dissipation device, the limitation due to the motherboard design, and the thermal contact surface, may limit the heat dissipation performance of the device.

### SUMMARY OF THE INVENTION

The invention is to solve the above disadvantages of the conventional liquid-cooling heat dissipation device. Through researches and practices, to make the working medium of the liquid-cooling configuration perform a liquid-vapor phase transition similar to that of a thermosiphon cooling system can remove more heat generated by the heat source. Once a fan is employed to cool the heat-dissipating end of the siphon-type heat dissipation device, the heat dissipation efficiency can be further improved.

Accordingly, the invention provides a server heat dissipation structure configured to dissipate the heat of the host casing of dense-type server, and including siphon-type heat dissipation device and fan assembly;

The siphon-type heat dissipation device includes a heat-absorbing end and a heat-dissipating end that are connected via the connection tube;

The fan assembly is disposed on a side of the heat-dissipating end so as to help the heat dissipation of the heat-dissipating end.

In the aforementioned server heat dissipation structure, each fan in the fan assembly is detachable and can be respectively detached.

In the aforementioned server heat dissipation structure, the fan assembly includes six fans, where five of the six fans form a set and are fixed into a single piece, and the other one of the six fans is redundant fan that can be detached in a convenient manner.

In the aforementioned server heat dissipation structure, liquid is input into the heat-absorbing end and the heat-absorbing end outputs gas; gas is input into the heat-dissipating end and the heat-dissipating end outputs liquid; the liquid output by the heat-dissipating end is input to the heat-absorbing end via a liquid channel, and the gas output by the heat-absorbing end is input to the heat-dissipating end via a gas channel.

In the aforementioned server heat dissipation structure, the heat-dissipating end is attached and fixed to a surface of a heat generating component.

In the aforementioned server heat dissipation structure, the heat-dissipating end is fixed via screw or thermal adhesive.

The aforementioned server heat dissipation structure further includes a power module, the power module obtains electricity from the cable connection pillar on the server frame via a floating cable clip, and the obtained electricity accesses the power distribution board inside the host casing.

In the aforementioned server heat dissipation structure, the power distribution board and the motherboard are connected via a gold finger.

In the aforementioned server heat dissipation structure, the power distribution board is disposed on a middle part of the motherboard.

Comparing to the related art, the technical solutions of the invention have the following advantages:

1. Being able to effectively utilize the space of the server for heat dissipation: the heat-dissipating end and the heat-absorbing end of the siphon-type heat dissipation device may be respectively disposed in two different places, the siphon-type heat dissipation device is small in size and provides a flexible installation that is very convenient in various places, such that the siphon-type heat dissipation device is not so limited by the interiors of the host casing. As such, it is possible to effectively utilize the available space in the host casing for the placement of the condenser for heat dissipation. The larger the available space in the host casing, the more noticeable the advantages contributed by the heat dissipation solution of the invention will be.

2. Saving power consumed by fan: the speed of the typical server fans is controlled using proportional-integral-derivative (PID), that is to say, the fan speed varies with the temperature of chip. As the temperature of the chip reduces, the fan speed is reduced accordingly. The power consumed by the fan can be effectively reduced using the heat dissipation solution of the invention.

3. Effectively reducing the temperature of the electronic component and thus being applicable to high-end chip.

4. Low cost for massive production: the siphon-type heat dissipation device of the invention may be made of aluminum material. Comparing to the fin and heat pipe made of copper, the cost of the siphon-type heat dissipation device is significantly reduced; the particular quantity of the fan assembly can be changed, this helps save cost.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 shows an arrangement in a host casing according to one embodiment of the invention;

FIG. 2 is a schematic diagram of a fan assembly of one embodiment of the invention;

FIG. 3 is a schematic diagram of a siphon-type heat dissipation device according to one embodiment of the invention;

FIG. 4 is a bottom view of the siphon-type heat dissipation device in FIG. 3; and

FIG. 5 is a schematic view of a power module according to one embodiment of the invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In order to make the purposes and features more apparent, the embodiments of the invention are further described below with reference to the appending drawings. However, the invention can be realized in different forms and is not limited by the embodiments. Also, without confliction, the embodiments of the present application and features thereof can be combined or replaced. With the combination of the following descriptions, the advantages and features of the invention will be more clear.

It is noted that the structure, ratio, size or the like illustrated in the appending drawings are used as a reference of the disclosure of the specification for a person skilled in the art to understand and read but not for limiting the embodiments of the disclosure, and thus they do not have substantial meaning, without affecting the function and achieved purposes of the invention, any modification of the structure, variation of ratio or size are within the scope of the technical content disclosed by the invention. Also, terms such as “top”, “bottom”, “left”, “right”, “middle” and “one” used in the specification is also for the purpose of illustration but not for limiting the embodiments of the invention, without altering substantial technical content, the variation or alternation of the relative relationship thereof should within the scope of the invention.

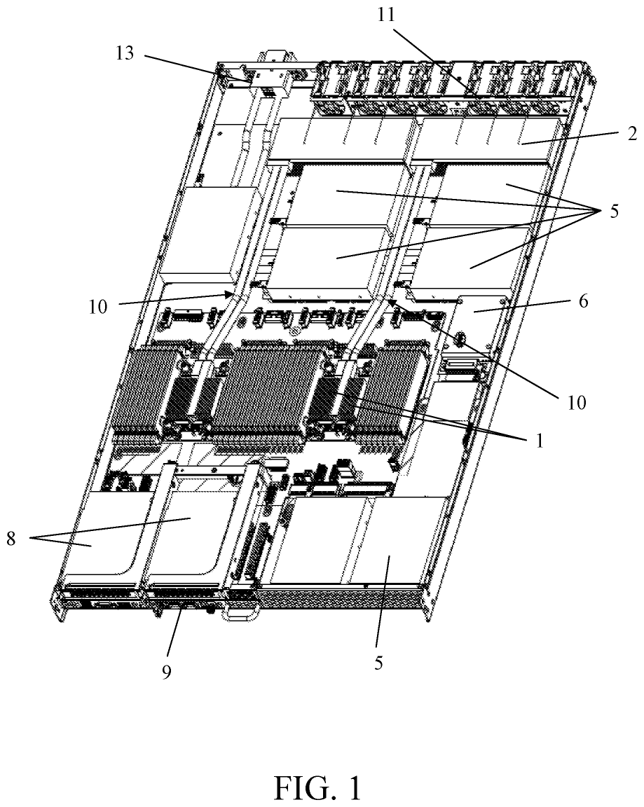

FIG. 1 shows an inner arrangement of a server (north pole 3.0). The server North pole 3.0 is a duo CPU (central processing unit) high-performance computing server with Intel whitley platform, its host casing is a standard 1 U host casing having a limited internal space, the height is particularly limited (the height of the available space in a 1 U host casing is only about 40 millimeters), but it requires to accommodate a total of 11 function modules including seven pieces of 3.5-inch hard disk drives (HDD) 5, a NVM express (NVME) disk drive 6, two pieces of full-height half-length peripheral component interconnect express (PCIE) cards 8, and an open compute project (OCP) 3.0 internet card 9 (OCP 3.0 internet card 9 is located under the full-height half-length PCIE card 8, and the drawing only shows its interface). The two full-height half-length PCIE cards 8 and the OCP 3.0 internet card 9 should be arranged at the front window. Also, in such a dense arrangement, it still needs a heat dissipation device 10 and a fan assembly 11 for the heat dissipation of the interiors of the host casing, thus the heat dissipation device and fan should be properly arranged.

The invention improves the arrangement of the heat dissipation device, fan heat dissipation device, and the fan. Firstly, the heat dissipation device 10 in FIG. 1 is a heat dissipation device using thermosiphon.

The heat dissipation process of the heat dissipation device using thermosiphon includes: liquid medium is input into heat-absorbing end 1 and absorbs sufficient heat (since the heat-absorbing end 1 is in tight contact with heat source) and then evaporates to a gas, the gas medium flows to the heat-dissipating end 2 through a gas tube 3. The heat-dissipating end 2 is a multi-blade structure that can facilitate the heat dissipation, it is also cooled by a fan, thus the gas medium is condensed into a liquid. The liquid medium is transferred back to the heat-absorbing end 1 through a liquid tube 4. Due to the temperature difference between the heat-absorbing end 1 and the heat-dissipating end 2, the gas tube 3 and the liquid tube 4 constantly have a pressure difference, and due to the siphon effect, liquid and gas medium can naturally form a loop.

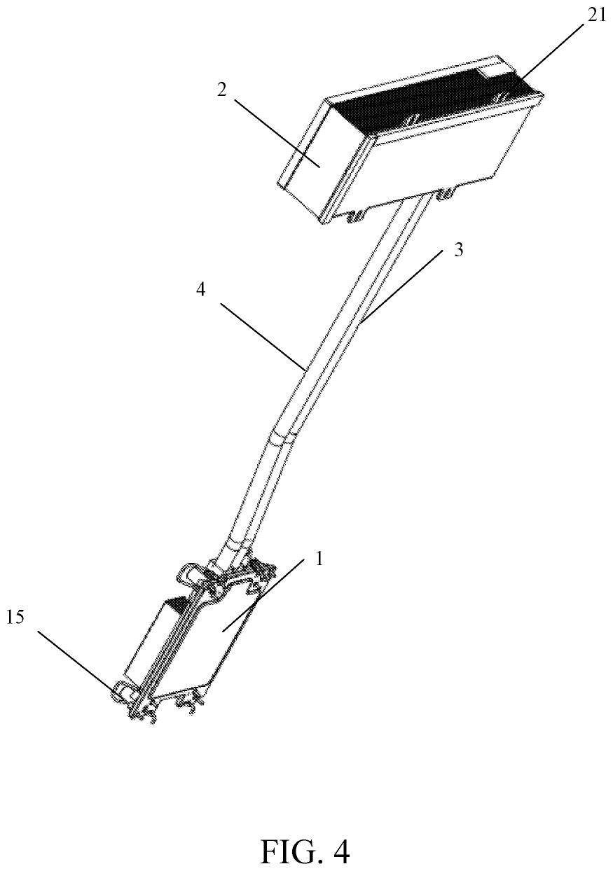

Please refer to FIG. 3 and FIG. 4, the siphon-type heat dissipation device includes the heat-absorbing end 1, the heat-dissipating end 2, the gas tube 3, and the liquid tube 4. The heat-absorbing end 1 and the heat-dissipating end 2 are connected via the gas tube 3 and the liquid tube 4. During the operation of the siphon-type heat dissipation device, the heat-absorbing end 1 should be in tight contact with the heat source, such as a computation node or a storage node, inside the server host casing. In the embodiment shown in FIG. 1, the heat-absorbing end 1 is disposed on the top surface of the CPU (in FIG. 1, the CPU is entirely covered by the heat-absorbing end 1); the heat-dissipating end 2 is disposed in an available space in the server host casing. In the embodiment shown in FIG. 1, the heat-dissipating end 2 is disposed at the position accessing the host casing rear window, and if the fan is not disposed in this area, the heat-dissipating end 2 may be directly disposed on the rear window. The heat-absorbing end 1 and the heat-dissipating end 2 can be separately disposed, enabling a convenient arrangement of the host casing. Since the heat-dissipating end of the heat dissipation device requires more spaces, and the heat generating component (heat source) is usually a computation chip with memories, communication devices and the like disposed around, it is difficult to find a sufficient space for the heat-dissipating end. The heat dissipation device shown in FIG. 3 and FIG. 4 separates the heat-absorbing end and the heat-dissipating end, such that the difficulty in arranging the heat-dissipating end is reduced. The heat-dissipating end 2 can be selectively to be disposed at a proper position in the host casing that is well ventilated.

Specifically, a first mount hole 15 is disposed on the heat-absorbing end 1, and a second mount hole 21 is disposed on the heat-dissipating end 2, such that the heat-absorbing end 1 and the heat-dissipating end 2 can be fixed in position via fasteners such as screws. To further improve the thermal conduction effect, thermal adhesive may be applied to fix the heat-absorbing end 1.

To reduce costs, in one preferable embodiment, all of the components of the siphon-type heat dissipation device are made of aluminum alloy.

Other components and modules may exist between the heat-absorbing end 1 and the heat-dissipating end 2. In order to not affect these components and modules, the paths that the gas tube 3 and the liquid tube 4 are routed should be designed according to the actual conditions of the components and modules, when necessary, these tubes may be bent to avoid structural interference.

In a case that the server has a sufficient available internal space, each heat source may be equipped with one siphon-type heat dissipation device shown in FIG. 3 and FIG. 4. In the embodiment shown in FIG. 1, there are two siphon-type heat dissipation devices respectively disposed on the two CPUs. By individually cooling the heat source, the heat dissipation efficiency is improved and the interference between the heat sources is also reduced.

In addition, in FIG. 1, the fan assembly 11 is further disposed on rear window of the host casing. As described above, the heat-dissipating end 2 of the heat dissipation device is disposed near the rear window, and therefore the fan assembly 11 and the heat-dissipating end 2 are located adjacent to each other, where the fan assembly 11 is mainly used to cool the heat-dissipating end 2.

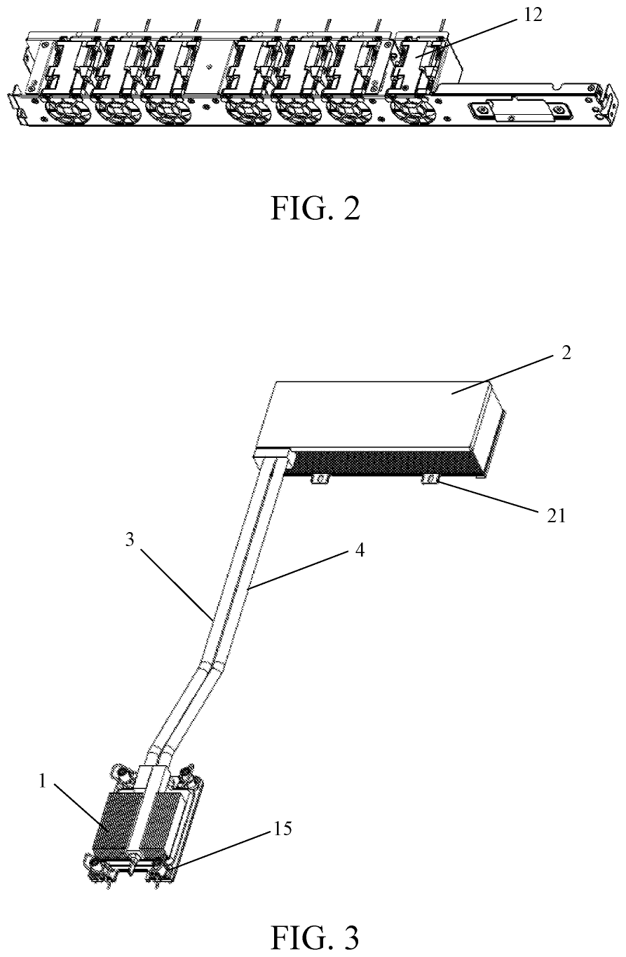

Specifically, since the technical solution of the invention is applicable to other types of host casing. Since the different host casings may have different heat dissipation requirements, preferably, fans of the fan assembly 11 may be are removable and can be respectively detached. That is, the fan assembly 11 may include one, two or more fans according to actual requirements. Also, the fan is preferably installed via engagement structures, this allows the fans to be directly detached from the rear window. In the embodiment shown in FIG. 1, there are six spots for the installation of fan. According to the requirements of the north pole 3.0 type server, as shown in FIG. 2, this embodiment use five of the fans as stationary fans that are undetachably fixed in place, and the fan 12 is used as a redundant fan that is fixed via detachable manner so that it can be removed when required.

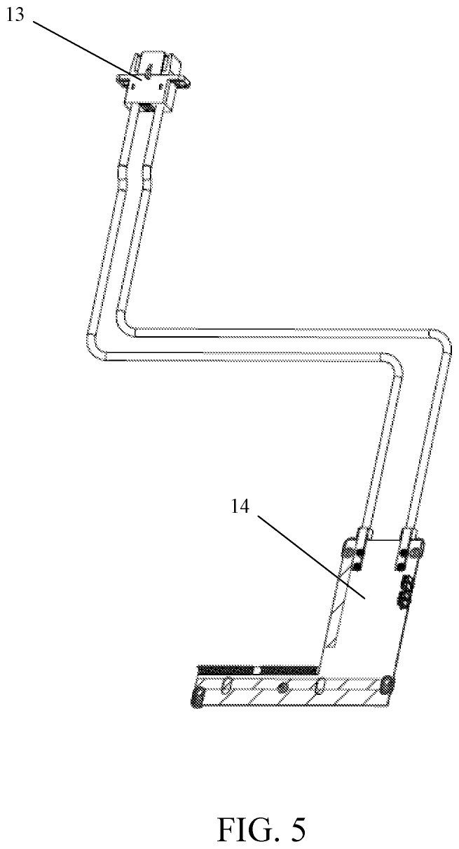

Further, as shown in FIG. 5, the invention further includes a power module. The power module is not entirely shown in FIG. 1, and FIG. 1 only shows that the floating cable clip 13 is disposed on a side of the fan assembly 11. Specifically, one end of the power module is the floating cable clip 13, the other end is a power distribution board 14, and they are connected via a conductive cables that is bent into a suitable shape. The power module introduces the electricity from the rear window of the host casing to a position of the host casing that is located adjacent to the middle part of the host casing, which enables the electricity to be distributed to electrical devices in a more uniform manner. The motherboard is connected to all of the modules in the host casing, and as the power port of the power distribution board 14 and the motherboard are connected, the electricity can be supplied to the whole server. For the purpose of installation, the power distribution board 14 and the power port are connected via gold finger.

The above server heat dissipation device can be arranged in a proper location in the host casing due to the flexible arrangement and high heat dissipation efficiency of the siphon-type heat dissipation device, realizing the dense arrangement of the components in the server host casing. As such, the difficulty in arranging the components in the host casing is reduced, the heat dissipation device is applicable to various types of host casing and can provides solution for similar issues.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A server heat dissipation structure, configured to dissipate the heat of a host casing of a dense type server, the server heat dissipation structure comprising a thermosiphon heat sink and a fan assembly;
the thermosiphon heat sink comprising a heat absorbing end and a heat dissipation end that are connected via a connection tube;
the fan assembly disposed on a side of the heat dissipation end so as to help the heat dissipation of the heat dissipation end.

2. The server heat dissipation structure according to claim 1, wherein a plurality of fans in the fan assembly are separating and detachable.

3. The server heat dissipation structure according to claim 1, wherein the fan assembly includes six fans, five of the six fans form a set and are fixed into a single piece, and another one of the six fans is a redundant fan that is convenient to be detached.

4. The server heat dissipation structure according to claim 1, wherein liquid is input into the heat absorbing end and the heat absorbing end outputs gas; gas is input into the heat dissipation end and the heat dissipation end outputs liquid; liquid output by the heat dissipation end is input to the heat absorbing end via a liquid channel, and gas output by the heat absorbing end is input to the heat dissipation end via a gas channel.

5. The server heat dissipation structure according to claim 1, wherein the heat dissipation end is attached and fixed to a surface of a heat generating component.

6. The server heat dissipation structure according to claim 5, wherein the heat dissipation end is fixed via a screw or a thermal adhesive.

7. The server heat dissipation structure according to claim 1, further comprising a power device, wherein the power device obtains electricity from a wire connection pillar on a server frame via a floating cable clip, and obtained electricity accesses a power distribution board inside the host casing.

8. The server heat dissipation structure according to claim 7, wherein the power distribution board and a motherboard are connected via a gold finger.

9. The server heat dissipation structure according to claim 7, wherein the power distribution board is disposed on a middle part of a motherboard.
